(19) United States
(12) Patent Application Publication
(10) Pub. No.: US 2002/0173074 A1
(43) Pub. Date: Nov. 21, 2002

(54) Method for underfilling bonding gap between flip-chip and circuit substrate

(75) Inventors: Su Chun-Jen, Kaohsiung (TW); Lai Chien-Hung, Kaohsiung (TW); Lin Chien-Tsun, Kaohsiung (TW); Chang Chao-Chia, Kaohsiung (TW)

Correspondence Address: DOUGHERTY & TROXELL, SUITE 404, 5205 LEESBURG PIKE, FALLS CHURCH, VA, 22041, US

(73) Assignee: Walsin Advanced Electronics LTD

(21) Appl. No.: 09/855,551

(22) Filed: May 16, 2001

(51) Int. Cl. H01L 21/44; H01L 21/48

(52) U.S. Cl. 438/108; 257/687

(57) ABSTRACT

A method for underfilling bonding gap between flip-chip and circuit substrate is disclosed. A chip is mounted on a circuit substrate with flip-chip configuration. The circuit substrate has a top surface, a bottom surface, and a plurality of via holes. Some of the via holes are formed to be air vents passing through the top surface and the bottom surface. So that the underfill material flows into the gap between flip-chip and circuit substrate until jamming or blocking the said air vents rapidly while underfilling.

### FIELD OF THE INVENTION

The present invention relates to a method for underfilling the gap between a flip-chip and a circuit substrate and, more particularly, to a method for underfilling a flip-chip package.

### BACKGROUND OF THE INVENTION

In the field of electrical connection between semiconductor chip and substrate, flip-chip mounting technique is more advanced than wire bonding technique. Steps in flip-chip mounting method are, forming a plurality of conductive bumps on one surface of the semiconductor chip (bonding pad), turning over the chip to mount on a circuit substrate, such as BGA board or printed circuit substratefor electrical connection the chip and the substrate in one time. This not only is more rapidly during the manufacturing process, but also can be used in the combination of high-density electronic components.

However, due to the mismatch of the coefficient of thermal expansion between the semiconductor chip and the substrate, the bumps in between the chip and the substrate bear great thermal stress during operation of the chip, and that result in thermal fatigue and failure of electrical connection. Thus, an underfill material, such as a thermosetting liquid epoxide, is filled into the gap between the chip and the substrate to reduce thermal stress that bumps bear and improve the usage durability of the semiconductor device.

There are several well-known methods for underfilling the gap between the chip and the substrate. One of them is U.S. Pat. No. 6,066,509 “method and apparatus for underfill of bumped or raised die”. FIG. 1. shows that a semiconductor assembly of a flip chip 12 and circuit substrate 11 with bump 13 is placed on a inclined plane. An underfill material 14 is dispensed into the gap between the flip chip 12 and the substrate 11 by injecting the underfill material 14 from an underfill dispenser 15 near front wall of the flip chip 12 and flowing toward rear sidewall of the flip chip 12 under capillary action and gravity. But this method requires long underfilling time and is not suitable for mass production.

Another method for forming an underfill material between chip and substrate is disclosed in U.S. Pat. No. 6,081,997—“System and method for packaging an integrated circuit using encapsulant injection”. FIG. 2. shows positioning a semiconductor assembly of a chip 22 and a circuit substrate 21 within a mold cavity, wherein the chip 22 has a plurality of bump 23 for mounting on the circuit substrate 21 and the mold cavity is defined by a top mold 26 and a bottom mold 25 with a injection opening 251. The injection opening 251 of the bottom mold 25 is aligned with an opening 211 of the circuit substrate 21. A plurality of air vents 261 is formed between connection edge of top mold 26 and bottom mold 25. While injecting underfill material 24 through the injection opening 251 and substrate openings 211 into the mold cavity such that the underfill material 24 fills the gap between chip 22 and circuit substrate 21 rapidly. This molding method of forming underfill has a drawback that the distribution of bumps on chip 22 should be redesigned due to the opening 211 of circuit substrate 21 for underfill material 24 flowing. The type of the chip and the distribution of bumps (bonding pads) of the chip are limited. Also the method is unsuitable for packaging a semiconductor chip with high-density I/O pads. Besides, during process of injecting underfill material 24 upwardly, an injection force is generated to push chip 22 away from circuit substrate 21 resulting in missing connection of bump 23. The height of the mold cavity bounded by top mold 26 and bottom mold 25 has to match the height of the assembly of chip 22 and circuit substrate 21, otherwise the bumps 23 will be separated from circuit substrate 21 or chip 22. But it is difficult to request all the same thicknesses of different assemblies of chip 22 and circuit substrate 21 in every molding time.

### SUMMARY OF THE INVENTION

The first object of the present invention is to provide a method for underfilling a gap between a flip chip and a circuit substrate rapidly with excellent production yield. The circuit substrate for bonding the chip comprises of a top surface, a bottom surface and a plurality of via holes, wherein some of the via holes are formed as air vents passing through the top surface and the bottom surface. When injecting the underfill material from the top surface of the circuit board mounting with the flip chip, there is a suck force to attract the underfill material into the gap between flip chip and circuit substrate and fill the said air vents for rapid underfilling and high yield.

The second object of the present invention is to provide a flip-chip package. The flip chip package comprises a chip in flip-chip form being mounted to a circuit substrate. The circuit substrate has a top surface, a bottom surface and a plurality of via holes. Some of the via holes are air ventspassing through the top surface and the bottom surface for filling an underfill material.

According to the method for underfilling bonding gap between flip-chip and circuit substrate, at least comprises:

at least a chip flip-chip mounting to top surface of a circuit substrate, and forming a gap between the chip and circuit substrate, wherein the circuit substrate having a top surface, a bottom surface and a plurality of via holes, some of via holes are formed to be air-passing through holes traversing through top surface and bottom surface; and

providing a underfill material on top surface of circuit substrate, forcing the underfill material to flow into the gap between the chip and circuit substrate jam said via holes.

### BRIEF DESCRIPTION OF THE DRAWINGS

FIG. 1 is a cross-sectional view of a method for underfill of bumped or raise die disclosed in U.S. Pat. No. 6,066,509;

FIG. 2 is a cross-sectional view of a method for packaging an integrated circuit using encapsulant injection disclosed in U.S. Pat. No. 6,081,997;

FIG. 3a is a cross-sectional view of an assembly of flip chip and circuit board clipped by top mold and bottom mold in molding and vacuuming step of a method for underfilling bonding gap between a flip-chip and a circuit substrate according to a first embodiment of the present invention;

FIG. 3b is a cross-sectional view of an assembly of flip chip and circuit board with an underfill material after injecting and curing step of a method for underfilling bonding gap between a flip-chip and a circuit substrate according to a first embodiment of the present invention;

FIG. 3c is a cross-sectional view of a flip chip package after removing molds and planting solder balls step of a method for underfilling bonding gap between a flip-chip and a circuit substrate according to a first embodiment of the present invention;

FIG. 4a is a cross-sectional view of an assembly of flip chip and circuit board clipped by top mold and bottom mold in molding and vacuuming step of a method for underfilling bonding gap between a flip-chip and a circuit substrate according to a second embodiment of the present invention;

FIG. 4b is a cross-sectional view of an assembly of flip chip and circuit board with an underfill material after injecting and curing step of a method for underfilling bonding gap between a flip-chip and a circuit substrate according to a second embodiment of the present invention; and

FIG. 4c is a cross-sectional view of a flip chip package after removing molds and planting solder balls step of a method for underfilling bonding gap between a flip-chip and a circuit substrate according to a second embodiment of the present invention.

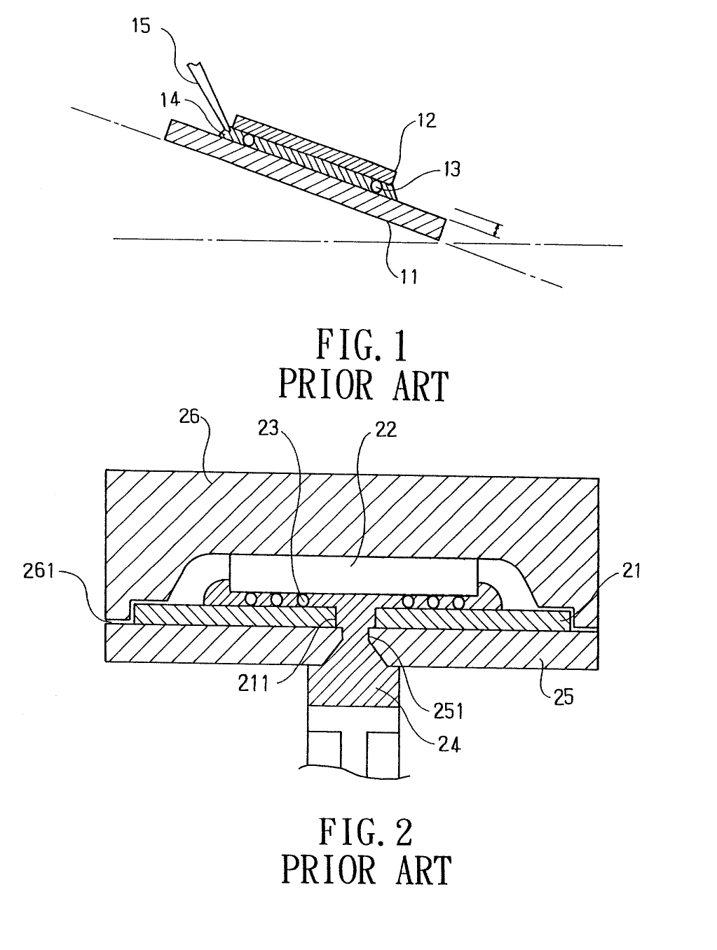

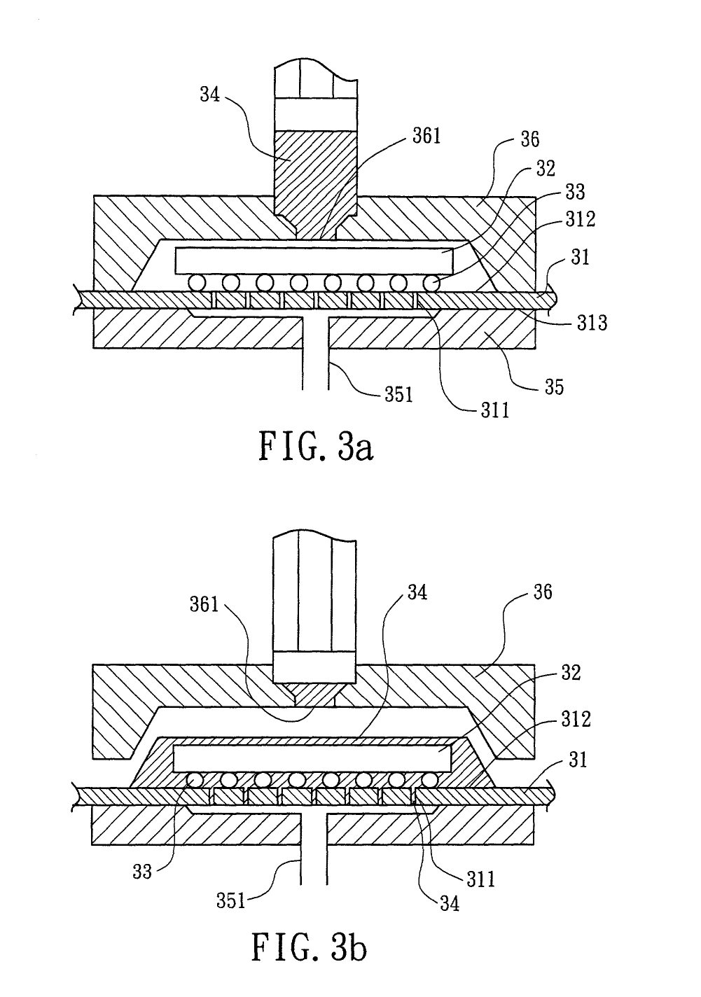

### DETAILED DESCRIPTION OF THE PREFERRED EMBODIMENT

Referring now to the drawings, the individual embodiments according to the present invention will be described.

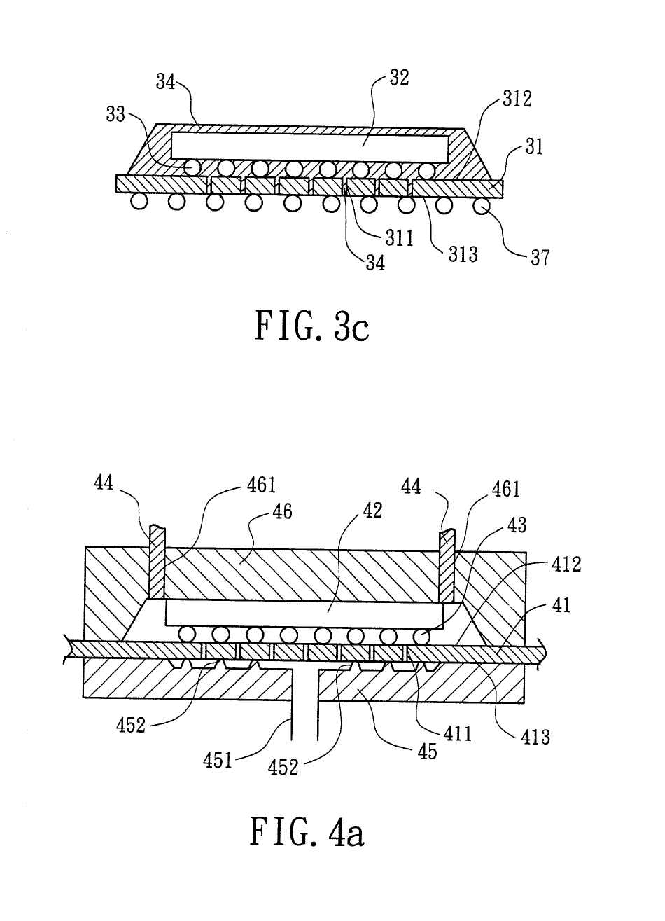

FIGS. 3a, 3b and 3c show the steps of filling underfill material according to the first embodiment of the present invention. As shown in FIG. 3a, first a circuit substrate 31, such as a printed circuit board or a BGA substrate, is provided. In this embodiment, the circuit substrate 31 is a BGA substrate made from FR4 or BT resin mixing with fiberglass.

The circuit substrate 31 comprises of a top surface 312, a bottom surface 313 and a plurality of via holes. It is well known that there is proper circuit pattern on both top surface 312 and bottom surface 313 of the circuit substrate 31. For example, there are a plurality of first connection pads (not illustrated in figures) on the top surface 312 for electrically connecting chip 32, and a plurality of second connection pads (not illustrated in figures) on the bottom surface 313 for electrically connecting solder balls 37 (as shown in FIG. 3c), as well as via holes electrically connecting first connection pads on top surface 312 and second connection pads on bottom surface 313. Some of electroplated via holes form air vents 311 which pass through top surface 312 and bottom surface 313 for air flowing.

The chip 32 is a semiconductor chip, such as a microprocessor chip, a memory chip, or a system-on-chip, made from silicon or arsenide gallium. The chip 32 comprises integrated circuit elements and a plurality of bonding pads (not illustrated in figures) on bottom surface of the chip 32. There is a bump 33, made from gold or lead-tin alloy for instance, formed on each bonding pad of the chip 32. By applying surface mounting technique of flip-chip and reflowing, the bumps 33 of chip 32 electrically connect to corresponding connection pads of top surface 312 of circuit substrate 31 so that chip 32 forms a flip-chip configuration. Due to these bumps 33 a gap between chip 32 and circuit substrate 31. Another substitute method to electrically connect chip 32 and circuit substrate 31 is to settle bumps 33 on the circuit substrate 31 for mounting chip 32. The bumps 33 are provided as solder material for electrically connecting chip 32 and circuit substrate 31 and are made from gold, silver, indium, tin lead or other alloy, even conductive polymer or conductive epoxy compound.

Then the assembly of chip 32 and circuit substrate 31 is clipped by top mold 36 and bottom mold 35, forming a molding cavity. An injection hole 361 is formed on the top mold 36 corresponding to above the chip 32 for dispensing underfill material 34. A vacuum tunnel 351 is formed on the bottom mold 35 corresponding to beneath the chip 32 to connect to vacuum facility (not illustrated in figures). In this embodiment, the process is first vacuuming the molding hole through vacuum channel 351, and then dispensing underfill material 34 from injection hole 361 on top of the chip 32. The underfill material 34 fill up molding cavity and flow into gap between chip 32 and circuit substrate 31, and finally jam (or partially fill) air vents 311 of circuit substrate 31. It is better that underfill material 34 fills air vents 311 of circuit substrate 31. The underfill material is made from an epoxy or acrylic resin or which may contain a little inert filler material, such as silica. During filling, viscosity of underfill material 34, gap size between chip 32 and circuit substrate 31, size of air vents 311 and air-extracting down pressure should be taken into account. It is better that the air vents 311 allow air flow to pass through, but not allow underfill material 34 to pass through for acting as mechanism of filter. Thus, by processing said steps, underfill material 34 can rapidly fill up gap between chip 32 and circuit substrate 31 and seal the bumps 33.

Then, after curing underfill material 34, as shown in FIG. 3b, remove top mold 36 to take out an assembly of chip 32 and circuit substrate 31 with underfill material 34. As well known, after planting solder balls and dicing, come out a flip-chip BGA package(flip-chip package) structure as shown in FIG. 3c. In this embodiment, a flip-chip package comprises of a circuit substrate 31, a chip 32, and an underfill material 34. The circuit board 31 has a top surface 312, a bottom surface 313 and a plurality of via holes. Some of the via holes (or all the via holes) are formed to be air vents 311 which pass through top surface 312 and bottom surface 313. The chip 32 is electrically connected to top surface 312 of circuit substrate 31 by a plurality of bumps 33, and which form a gap between the chip 32 and the circuit substrate 31. The underfill material 34 fills the gap and jam said air vents 311. It is better that the underfill material 34 fills said air-passing through holes 311 and seals the chip 32. A plurality of solder balls 37 is formed on bottom surface 313 of the circuit substrate 31 to make the flip-chip package in Ball Grid Array package form. Or, form a plurality of connection pads but not solder balls 37 on bottom surface 313 of the circuit substrate 31 to make flip-chip package as Land Grid Array package.

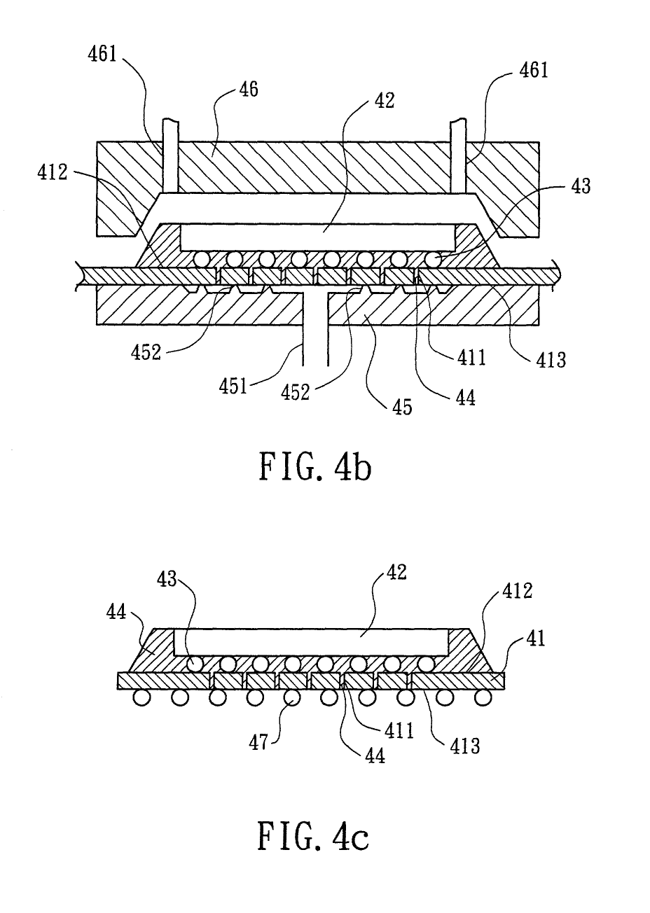

FIGS. 4a, 4b and 4c show steps of filling underfill material according to the second embodiment of the present invention. As shown in FIG. 4a, a circuit substrate 41 is provided. The circuit substrate 41 is a BGA substrate made from ceramic or resin. The circuit substrate 41 comprises of a top surface 412, a bottom surface 413 and a plurality of via holes. Some of the electroplated via holes (or all the via holes) form air vents 411 which pass through top surface 412 and bottom surface 413 for air flow.

The chip 42 is a semiconductor chip, such as a microprocessor chip, a memory chip, or a system-on-chip. The bottom surface of chip 42 comprises integrated circuit elements and a plurality of bonding pads (not illustrated in figures). A bump 43 is formed on each bonding pad of the chip 42. Via the bumps 43, chip 42 is electrically connected to top surface 412 of circuit substrate 41 in flip-chip form. And these bumps 43 form a gap between chip 42 and circuit substrate 41.

Then said assembly of chip 42 and circuit substrate 41 is clipped by top mold 46 and bottom mold 45 in a molding cavity. The top mold 46 contacts tightly to top surface of the chip 42. A plurality of injection holes 461 are formed on top mold 46 around the chip 42. A vacuum channel 451 is formed on the bottom mold 45 corresponding to beneath the circuit substrate 41. A plurality of support pillars 452 are formed on the bottom mold 45 to support the circuit substrate 41. The vacuum channel 451 is connected to a vacuum facility (not illustrated in figures). In this embodiment, the process is first dispensing underfill material 44 from injection hole 461 around the chip 42. Simultaneously, extract air in the molding cavity through vacuum channel 451 to form an air flow path. By force of suction, gravity and capillarity, the underfill material 44 in the molding cavity flows into the gap between chip 42 and circuit substrate 41 until blocking the air vents 411 of circuit substrate 41. It is better that the underfill material 44 jams air vents 411 of circuit substrate 41, so that underfill material 44 can rapidly fill up the gap between chip 42 and circuit substrate 41 and seal the bumps 43.

Then, after curing the underfil material 44, as shown in FIG. 4b, remove top mold 46 and take out an assembly chip 42 and circuit substrate 41 with underfill material 44. After well known planting solder balls and dicing, come out a flip-chip BGA package structure as shown in FIG. 4c. In this embodiment, a flip-chip package comprises of a circuit substrate 41, a chip 42, and an underfill material 44. The circuit substrate 41 has a top surface 412, a bottom surface 413 and a plurality of via holes. Some of the via holes (or all the via holes) are formed to be air vents 411 passing through top surface 412 and bottom surface 413. The chip 42 is electrically connected to top surface 412 of circuit substrate 41 by a plurality of bumps 43, and which form a gap between the chip 42 and the circuit substrate 41. The underfill material 44 fills the gap and block said air vents 411. It is better that the underfill material 44 fill up said air vents 411, but exposes top surface of the chip 42. A plurality of solder balls 47 is formed on bottom surface 413 of the circuit substrate 41 to make the flip-chip package in Ball Grid Array package form.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method for underfilling bonding gap between flip-chip and circuit substrate comprising the steps of:
providing a circuit substrate having a top surface, a bottom surface and a plurality of via holes, wherein at least some of the via holes are air vents passing through the top surface and the bottom surface;
mounting at least a chip with flip-chip configuration connecting to the top surface of the circuit substrate so that a gap is formed between the chip and the circuit substrate; and
dispensing an underfill material on top surface of circuit substrate so that the underfill material flows to the gap between the chip and the circuit substrate and blocks said air vents.

2. The method of claim 1 further comprising the step of: molding the assembly of the chip and the circuit substrate before dispensing the underfill material.

3. The method of claim 2 further comprising the step of: extracting air under the bottom surface of the circuit substrate so as to form air-flowing path from the gap to the air vents.

4. The method of claim 2 further comprising the step of: vacuuming the gap between the chip and the circuit substrate.

5. A process for filling an underfill material of a flip-chip package comprises:
providing a circuit substrate, having a top surface, a bottom surface and a plurality of via holes, wherein some of the via holes are air vents passing through the top surface and the bottom surface;
providing a chip having a plurality of bumps on one surface of the chip;
mounting the chip to the top surface of the circuit substrate in flip-chip form with bumps for electrically connecting the chip and the circuit substrate and forming gap between the chip and the circuit substrate; and
dispensing an underfill material on the top surface of the circuit substrateso that the underfill material flows up the gap between the chip and the circuit substrate and blocks said air vents.

6. The process of claim 5 further comprising the step of: molding the assembly of the chip and the circuit substrate before dispensing the underfill material.

7. The process of claim 6 further comprising the step of: extracting air under the bottom surface of the circuit substrate so as to form air-flowing path from the gap to the air vents.

8. The process of claim 5 further comprising the step of: vacuuming the gap between the chip and the circuit substrate.

9. A flip-chip package comprising:
a circuit substrate having a top surface, a bottom surface and a plurality via holes, wherein at least some of the via holes are air vents passing through the top surface and the bottom surface;
a chip electrically connecting to the top surface of the circuit substrate with flip-chip configuration and forming a gap with the circuit substrate; and
an underfill material filling up the gap and blocking said air vents.

10. The flip-chip package of claim 9, wherein the underfill material fills said air vents.

11. The flip-chip package of claim 9, wherein the underfill material seals the chip.

12. The flip-chip package of claim 9, further comprising a plurality of solder balls connecting to the bottom surface of the circuit substrate.
